(19) United States
(12) Patent Application Publication
(10) Pub. No.: US 2026/0348299 A1
(43) Pub. Date: Nov. 5, 2026

(54) COATING COMPRISING HAFNIUM

(71) Applicant: SAFRAN, PARIS (FR)

(72) Inventors: Amar SABOUNDJI, MOISSY-CRAMAYEL (FR); Luc Patrice BIANCHI, MOISSY-CRAMAYEL (FR)

(21) Appl. No.: 19/124,618

(22) PCT Filed: Oct. 18, 2023
(86) PCT No.: PCT/FR2023/051626

§ 371 Date: Apr. 25, 2025

(30) Foreign Application Priority Data
Oct. 26, 2022 (FR) 2211157

(51) Int. Cl. F01D 25/00; C23C 16/06; C23C 16/56

(52) U.S. Cl. CPC F01D 25/005; C23C 16/06; C23C 16/56; F05D 2230/31; F05D 2230/40; F05D 2300/135; F05D 2300/143; F05D 2300/175; F05D 2300/611

(57) ABSTRACT

A method for forming a coating on a surface of a metal substrate, the method includes a) depositing a hafnium layer the thickness e of which is between 0.2 μm and 10 μm; b) depositing a layer of platinum the thickness of which is between 2.0 μm and 10 μm; and c) aluminizing the part obtained after a) and b).

### TECHNICAL FIELD

The invention relates to the field of metal parts coated with a thermal barrier and more specifically to bonding layers to increase the adhesion between the thermal barrier and the metal parts.

### PRIOR ART

Generally speaking, the performance of an aeronautical turbomachine depends on the temperatures reached.

However, the high temperatures and the particular chemical environment of turbomachines subject the turbomachine parts to significant stresses.

Typically, materials used for parts in such environments are coated with a thermal barrier and/or an environmental barrier to improve their lifetimes.

To improve the adhesion of the thermal barrier to a substrate, it is generally proposed to interpose a bonding layer, also called a “sub-layer” between the substrate and the thermal barrier, the bonding layer fulfilling two main roles: protecting the substrate against oxidation and corrosion and promoting the adhesion of the thermal barrier.

The adhesion of the bonding layer to the substrate and the thermal barrier is important because it increases the lifetime of the thermal barrier and, consequently, of the entire part.

To improve the adhesion of the part, it is sometimes suggested to dope the bonding layer with hafnium. Two solutions exist for this purpose, but neither is completely satisfactory.

According to a first option, it is possible to add a large amount of hafnium to the composition of the substrate, so that the amount of hafnium migrating by diffusion into the bonding layer, when it is produced, is greater.

This option, however, requires changing the composition of the metal substrate, which is rarely desirable. Furthermore, it requires working with substrates with a higher hafnium content, which makes it more difficult to dissolve the hafnium in the substrate.

According to a second option, it is possible to add a small amount of hafnium to the bonding layer directly during its deposition.

Unfortunately, when trying to put this option into practice, it is found that the amount of hafnium and the homogeneity of the distribution of hafnium in the thickness of the bonding layer are not perfectly controlled. There is therefore a risk of degrading the oxidation life and the resistance of the thermal barrier.

Therefore, there remains a need for a method for manufacturing a bonding layer that allows to control the amount of hafnium and the homogeneity of its distribution in the bonding layer.

### DISCLOSURE OF THE INVENTION

The invention aims precisely at meeting this need and proposes, according to a first of its aspects, a method for forming a coating on a surface of a metal substrate, the method comprising at least the following steps:
(a) depositing a hafnium layer the thickness of which is between 0.2 μm and 10 μm;
(b) depositing a platinum layer the thickness of which is between 2.0 μm and 10 μm;
c) aluminizing the part obtained after steps a) and b).

The method is advantageously better controlled and more repeatable than the methods of the prior art. Furthermore, it provides a coating that provides improved lifetime for the final part, after a thermal barrier is deposited on the coating, compared to prior art parts.

In one embodiment, the coating is a bonding layer for a thermal barrier, for example a bonding layer comprising nickel, platinum and aluminum which is doped with hafnium.

Indeed, the coating described can be used as a bonding layer for a thermal barrier on a metal substrate. Such a bonding layer will have all the advantages of the presence of hafnium described above and will also have good homogeneity of the hafnium in the bonding layer, without the need to modify the composition of the metal substrate.

In one embodiment, steps a) and b) may be carried out by chemical vapor deposition (or CVD) methods or physical vapor deposition (or PVD) methods. In one embodiment, the deposition of the platinum layer in step b) is carried out by electrolytic deposition.

In one embodiment, step b) may or may not be followed by a diffusion heat treatment.

For example, such diffusion heat treatment can be carried out at a temperature between 1050 °C and 1100 °C and for a duration between 30 minutes and 2 hours and at a pressure between 10-5 and 10-6 mbar.

However, such diffusion heat treatment is not necessary, since it was observed that the subsequent aluminization step c) already allowed good diffusion of the species between the layers deposited during steps a) and b).

The method is not limited by the relative organization of steps a) and b).

In one embodiment, step b) is carried out after step a).

In one embodiment, step b) is carried out before step a).

The presence of the hafnium layer helps to strengthen the grain boundaries in the coating, which helps to block the diffusion of metal cations and also slows down the diffusion of oxygen.

Furthermore, the presence of hafnium in the coating also helps block the diffusion of sulfur, whether it comes from the substrate or from the platinum electrolytic deposition.

The presence of the platinum layer provides the platinum needed to form the desired coating.

Also, the thicknesses of the platinum and hafnium layers ensure that the content of these elements in the final part is as desired.

The aluminization step c) is a step known as such. Applied to the method of the invention, it allows on the one hand an enrichment of the aluminum coating, and also the diffusion of the species present in the hafnium and platinum layers or else the species present in the substrate to form, on the surface of the substrate, a single coating layer, for example a bonding layer.

The aluminization step forms a surface layer of the coating which comprises a significant content of aluminum, platinum and nickel which also comprises hafnium, due to the diffusion of these species from the substrate or the layers deposited in steps a) and b).

Indeed, after aluminization, the layers of platinum and hafnium formed during steps a) and b) are no longer discrete because the diffusion caused by aluminization has allowed the mixing of the elements of these two layers in the formed layer.

In one embodiment, the aluminization may be carried out at a temperature between 980 °C and 1150 °C, preferably between 1040 °C and 1150 °C for a duration of between 2 and 8 hours, for example between 2 and 3 hours.

After the aluminization treatment of step c), the coating is no longer present in the form of separate layers but in the form of a single layer comprising all the species that diffused during aluminization.

Such a coating in particular comprises a high and homogeneous hafnium content, compared to the coatings obtained by methods of the prior art.

In one embodiment, the aluminization step is carried out without additional supply of hafnium.

Indeed, the presence of the hafnium layer deposited during step a) is sufficient to guarantee the beneficial effects of the presence of hafnium without it being necessary to provide more.

The aluminization step without additional hafnium is much easier and does not require adaptation of existing aluminization methods compared to an aluminization step during which one would also like to add hafnium.

Since hafnium has a high affinity for sulfur, the latter remains blocked in the presence of hafnium and therefore no longer migrates towards the layer formed by aluminization.

This results in better adhesion of the thermal barrier layer to the bonding layer, as sulfur is known to cause the bonding layer to detach, and therefore impair the performance of the thermal barrier.

Furthermore, the contribution of hafnium in the form of a thin layer rather than a deposition made jointly with the formation of the bonding layer ensures excellent homogeneity of the distribution of hafnium in the bonding layer.

According to another of its aspects, the invention also relates to a method for manufacturing a metal part coated with a thermal barrier comprising at least the following steps:
forming a coating on a surface of a metal substrate by a method as just described;
depositing a thermal barrier on said coating.

The invention is not limited by the nature of the thermal barrier, or the method for depositing the latter on the coating.

As has just been described, this embodiment allows to have bonding layers guaranteeing better adhesion and better resistance to oxidation of the thermal barriers than the bonding layers of the prior art.

Thus, the parts according to the invention have better resistance over time than those of the prior art, the sub-layers of which would be different.

In one embodiment, the thermal barrier may comprise yttria-stabilized zirconia (often referred to as YSZ) or gadolinium zirconate, of formula Gd₂Zr₂O₇ (often called GdZ).

In one embodiment, the thermal barrier may be deposited by suspension plasma spraying (or SPS), or by electron beam physical vapor deposition (or EBPVD) methods. For example, the thermal barrier may comprise a single layer of yttria-stabilized zirconia or a layer of yttria-stabilized zirconia and a layer of gadolinium zirconate.

According to another of its aspects, the invention relates to a coated metal part comprising:
a metal substrate;
a hafnium layer the thickness of which is between 0.2 μm and 10 μm, and disposed on one face of the substrate; and
a platinum layer the thickness of which is between 2.0 μm and 10 μm, and disposed on the hafnium layer, on the side of the hafnium layer opposite the substrate.

According to another of its aspects, the invention relates to a coated metal part comprising:
a metal substrate;
a platinum layer the thickness of which is between 2.0 μm and 10 μm, and disposed on one face of the substrate; and
a hafnium layer the thickness of which is between 0.2 μm and 10 μm and disposed on the platinum layer, on the side of the platinum layer opposite the substrate.

These two stacks allow, after an aluminization step c), as described above, to obtain a coating comprising a high and homogeneous hafnium content.

For example, the metal substrate may be selected from nickel superalloys known as AM1, N5, AM21, MCNG or CMSX10.

In one embodiment, the platinum layer comprises platinum at greater than 90% by mass, or even greater than 99% by mass. For example, the platinum layer does not comprise any element other than platinum and unavoidable impurities.

In one embodiment, the hafnium layer comprises hafnium at greater than 90% by mass, or even greater than 99% by mass. For example, the hafnium layer does not comprise any element other than hafnium and unavoidable impurities.

The invention is not limited by the relative arrangement of the hafnium layer and the platinum layer.

In one embodiment, the hafnium layer is located between the metal substrate and the platinum layer and preferably directly in contact therewith.

Such an embodiment allows to strengthen the grain boundaries of the sub-layer, thus blocking the diffusion of metal cations and slowing down the diffusion of oxygen therein and therefore the oxidation kinetics of the sub-layer and to neutralize the sulfur from the substrate.

In one embodiment, the hafnium layer is located on the platinum layer and preferably directly in contact therewith.

Such an embodiment allows to reinforce the grain boundaries of the sub-layer, thus blocking the diffusion of metal cations and slowing down the diffusion of oxygen therein and therefore the oxidation kinetics of the sub-layer.

Furthermore, this neutralizes sulfur from the substrate and platinum depositions, ensuring even longer thermal barrier lifetime. Sulfur is known to cause the detachment of the bonding layer.

In one embodiment, the metal substrate is a turbomachine blade or a turbomachine nozzle.

### BRIEF DESCRIPTION OF THE DRAWINGS

FIG. 1 schematically shows a method according to one embodiment of the invention.

FIG. 2 schematically shows a method according to another embodiment of the invention.

FIG. 3 schematically shows a part according to one embodiment of the invention.

FIG. 4 schematically shows a part according to another embodiment of the invention.

FIG. 5 schematically shows a part according to another embodiment of the invention.

FIG. 6 shows test results comparing two parts according to the invention with two parts of the prior art.

FIG. 7 is a micrograph obtained by scanning electron microscopy, identifying measurement points of the atomic composition of a bonding layer obtained by a method of the invention.

### DESCRIPTION OF THE EMBODIMENTS

The invention is now described by means of figures, present for descriptive purposes to illustrate certain embodiments of the invention and which should not be interpreted as limiting the latter. In particular and unless otherwise stated, the figures are represented without scale, and the relationships between the distances are not intended to be realistic.

As described, the invention relates to a method 2000, comprising the following steps:
a) depositing a hafnium layer the thickness of which is between 0.2 μm and 10 μm;
b) depositing a platinum layer the thickness of which is between 2.0 μm and 10 μm;
c) aluminizing the part obtained after steps a) and b).

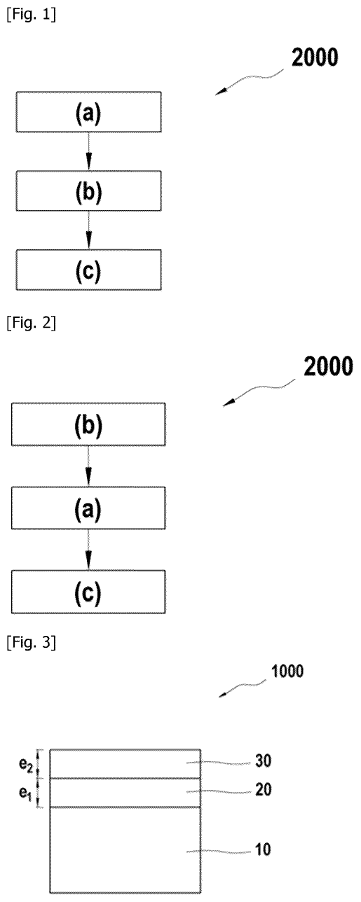

According to a first embodiment of the invention, described in FIG. 1, step a) is carried out before step b).

According to another embodiment of the invention, described in FIG. 2, step b) is carried out before step a).

Indeed, it is not necessary, in order to obtain the technical effect of the invention, for the deposition of the platinum layer to be carried out specifically before or after the deposition of the hafnium layer, provided that these two layers are deposited before the aluminization step.

In one embodiment, the aluminization step can be carried out in a manner known per se.

Generally, aluminization methods are carried out by contacting the superalloy with gas aluminum precursors, for example FAlCl₃, under pressure and temperature conditions which allow the formation of gas aluminum. The aluminum thus formed reacts with the nickel of the substrate which diffuses towards the surface of the substrate, with the help of temperature to form a layer comprising nickel and aluminum on the surface of the substrate, for example Ni₂Al₃.

Furthermore, in the method of the invention, the aluminization being carried out after the deposition of the platinum and hafnium layers, the layer formed by aluminization therefore also comprises these elements.

Of course, other elements present in the substrate can migrate by diffusion into the layer formed by aluminization.

For example, the coating comprises the elements of the substrate, plus a majority of nickel, platinum and aluminum as well as hafnium. Such a layer is often called NiPtAl, and is here doped with hafnium.

In one embodiment, the coating does not comprise any other elements present in a content of more than 5% by mass than nickel, aluminum and platinum.

In one embodiment, the coating further comprises up to 5% by weight of chromium and/or cobalt.

In one embodiment, the coating comprises between 0.5 and 3% by mass of hafnium.

For example, an aluminization treatment can be carried out at a temperature between 1040 °C and 1080 °C, for a duration between 200 and 500 minutes, and with a flow rate of aluminum precursor, for example FAlCl₃ between 0.23 and 1.0 L·min⁻¹.

Unlike the methods of the prior art, the presence of the hafnium layer allowing the production of the bonding layer by diffusion ensures on the one hand the presence, and on the other hand a homogeneous distribution of the hafnium in the bonding layer, without requiring modification of the composition of the underlying substrate.

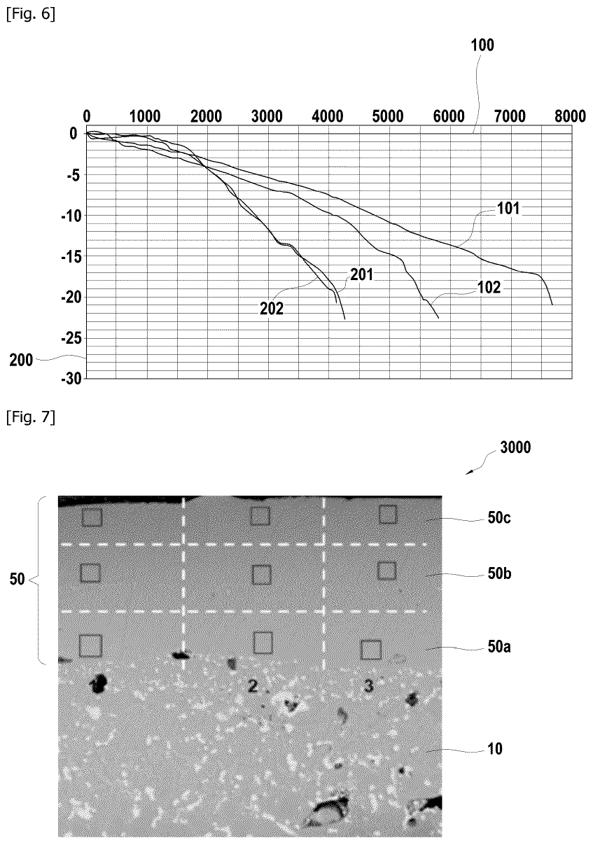

This ensures that the thermal barrier that will be deposited on the bonding layer has improved adhesion properties, which will improve the life of the part, as will be described in the example, in connection with FIG. 6.

FIG. 3 describes a part 1000 obtained at the end of the aluminization step c) of a method 2000 carried out in accordance with the embodiment of FIG. 1.

Such a part 1000 comprises:
a metal substrate 10;
a layer of hafnium 20 the thickness e₁ of which is between 0.2 μm and 10 μm;
a layer of platinum 30 the thickness e₂ of which is between 2.0 μm and 10 μm.

As indicated, the two layers 20, 30 are intended to form the bonding layer 50 by aluminization.

In one embodiment and as shown, the hafnium layer 20 may be directly in contact with the substrate 10.

In one embodiment and as shown, the platinum layer 30 may be directly in contact with the hafnium layer 20, on the side opposite the substrate 10.

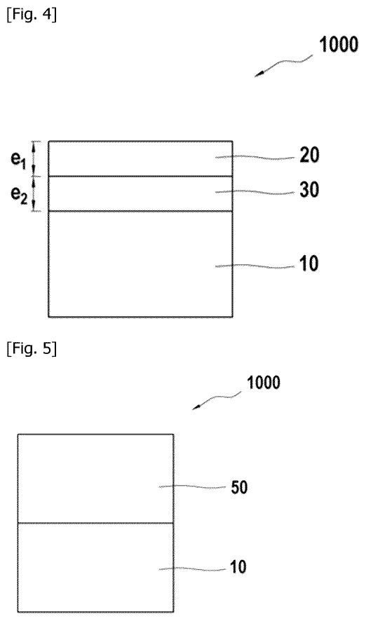

FIG. 4 describes a part 1000 obtained at the end of step c) of a method 2000 carried out in accordance with the embodiment of FIG. 2.

Indeed, the inversion of steps a) and b) has the effect of obtaining on the surface of the metal substrate 10 the platinum layer 30 and the hafnium layer 20 on the surface of the platinum layer 30.

In one embodiment and as shown, the platinum layer 30 may be directly in contact with the substrate 10.

In one embodiment and as shown, the hafnium layer 20 may be directly in contact with the platinum layer 30, on the side opposite the substrate 10.

FIG. 5 describes a part 1000 obtained after aluminization of a part as described in FIG. 3 or 4 indifferently.

Part 1000 no longer comprises two separate layers 20, 30 but a single layer 50, which further comprises aluminum provided by aluminization.

FIG. 6 illustrates comparative results of oxidation resistance for two parts according to the invention 101, 102 and two parts outside the invention 201, 202.

The four parts are similar and comprise a metal substrate, a bonding layer, and a thermal barrier disposed on the bonding layer.

However, the bonding layers of the parts outside the invention 201, 202 were obtained according to a method of the prior art, and do not comprise hafnium, whereas the parts according to the invention comprise hafnium and were obtained according to a method of the invention.

FIG. 6 shows the number of oxidation cycles on the abscissa 100, and the mass gain in mg·cm⁻² observed for the part on the ordinate 200. The experiments were carried out at 1150 °C.

It can be read in FIG. 6 that the mass loss (in FIG. 6, the mass gain 200 is in fact negative) is greater from 2000 cycles for the parts of the prior art than for the parts of the invention.

FIG. 7 aims at characterizing the homogeneity of the distribution of hafnium in a bonding layer 50 of the invention.

For this purpose, nine samples were taken, spaced according to three columns in the width of the sample (1, 2 and 3 in FIG. 7) and according to three layers 50a, 50b and 50c in the thickness, the sampling points being identified by squares.

The mass composition in 6 elements for six of the identified points is reported in Table 1.

TABLE 1

| | % by mass | 1 | 2 | 3 |
|---|---|---|---|---|
| 50b | Ni | 39 | 38 | 38 |
| | Al | 17 | 18 | 16 |
| | Pt | 36 | 36 | 37 |
| | Co | 4 | 5 | 5 |
| | Cr | 2 | 2 | 2 |
| | Hf | 1.2 | 1.6 | 1.6 |
| 50a | Ni | 37 | 37 | 36 |
| | Al | 16 | 16 | 15 |
| | Pt | 39 | 38 | 39 |
| | Co | 5 | 5 | 5 |
| | Cr | 3 | 3 | 3 |
| | Hf | 1.2 | 1.5 | 1.6 |

Table 1 clearly illustrates that the method of the invention allows to obtain small variations in the hafnium content in the bonding layer 50, the hafnium content remaining everywhere between 1.2% and 1.6% by mass.

1. A method for forming a coating on a surface of a metal substrate, the method comprising at least the following steps:
a) depositing a hafnium layer having a thickness between 0.2 μm and 10 μm, in which the hafnium layer comprises hafnium at greater than 90% by mass, carried out by a chemical vapor deposition method, a physical vapor deposition method or by electrolytic deposition;
b) depositing a platinum layer having a thickness between 2.0 μm and 10 μm, in which the platinum layer comprises platinum at greater than 90% by mass, carried out by a chemical vapor deposition method or a physical vapor deposition method;
c) aluminizing the part obtained after steps a) and b.

2. The method according to claim 1, wherein step b) is carried out after step a).

3. The method according to claim 1, wherein step b) is carried out before step a).

4. The method according to claim 1, wherein step b) is followed by a diffusion heat treatment.

5. The A method for manufacturing a metal part coated with a thermal barrier comprising at least the following steps:
forming a coating on a surface of a metal substrate by a method of claim 1; and
depositing a thermal barrier on said coating.

6. A coated metal part comprising:
a metal substrate;
a hafnium layer having a thickness between 0.2 μm and 10 μm, and disposed on one face of the substrate; and
a platinum layer having a thickness between 2.0 μm and 10 μm and disposed on the hafnium layer, on a side of the hafnium layer opposite the substrate.

7. The A coated metal part comprising:
a metal substrate;
a platinum layer having a thickness between 2.0 μm and 10 μm and disposed on one face of the substrate; and
a hafnium layer having a thickness between 0.2 μm and 10 μm and disposed on the platinum layer, on a side of the platinum layer opposite the substrate.

8. The coated metal part according to claim 6, wherein
the metal substrate is selected from nickel superalloys known as AM1, N5, AM21, MCNG or CMSX10.

9. The coated metal part according to claim 6, wherein the metal substrate is a turbomachine blade or a turbomachine nozzle.

10. The coated metal part according to claim 7, wherein the metal substrate is selected from nickel superalloys known as AM1, N5, AM21, MCNG or CMSX10.

11. The coated metal part according to claim 7, wherein the metal substrate is a turbomachine blade or a turbomachine nozzle.
